(19) United States
(12) Patent Application Publication
(10) Pub. No.: US 2017/0117242 A1
(43) Pub. Date: Apr. 27, 2017

(54) CHIP PACKAGE AND METHOD FOR FORMING THE SAME

(71) Applicant: XINTEC INC., Taoyuan City (TW)

(72) Inventors: Yen-Shih HO, Kaohsiung City (TW); Tsang-Yu LIU, Zhubei City (TW); Po-Han LEE, Taipei City (TW); Chi-Chang LIAO, Pingtung City (TW)

(21) Appl. No.: 15/297,490

(22) Filed: Oct. 19, 2016

Related U.S. Application Data
(60) Provisional application No. 62/244,593, filed on Oct. 21, 2015.

(51) Int. Cl. H01L 23/00

(52) U.S. Cl. CPC H01L 24/16; H01L 24/81; H01L 2224/08265; H01L 2224/81815; H01L 2924/146; H01L 2924/1207; H01L 2924/1205; H01L 2924/1206

(57) ABSTRACT

A chip package is provided. The chip package includes a substrate. The substrate includes a sensing region or device region. The chip package also includes a first conducting structure disposed on the substrate. The first conducting structure is electrically connected to the sensing region or device region. The chip package further includes a passive element vertically stacked on the substrate. The passive element and the first conducting structure are positioned side by side.

### CROSS REFERENCE TO RELATED APPLICATIONS

This Application claims priority of U.S. Provisional Application No. 62/244,593, filed Oct. 21, 2015, the entirety of which is incorporated by reference herein.

### BACKGROUND OF THE INVENTION

Field of the Invention

The invention relates to chip package technology, and in particular to a chip package having a passive element and methods for forming the same.

Description of the Related Art

The chip packaging process is an important step in the fabrication of an electronic product. Chip packages not only protect the chips therein from outer environmental contaminants, but they also provide electrical connection paths between electronic elements inside and those outside of the chip packages.

In general, a chip package and another electronic element (such as a passive element) are disposed on a circuit board independently, and are indirectly electrically connected to each other. However, the size of the circuit board is limited. As a result, it is difficult to further decrease the size of an electronic product formed using the chip package. Furthermore, since electrical transfer paths between the chip package and another electronic element are long, attenuation of the power and/or signal of the electronic product is great. Also, noise is easily induced. Therefore, the quality of the electronic product is reduced.

Thus, there exists a need in the art for development of a chip package and methods for forming the same capable of mitigating or eliminating the aforementioned problems.

### BRIEF SUMMARY OF THE INVENTION

Embodiments of the invention provide a chip package including a substrate. The substrate includes a sensing region or device region. The chip package also includes a first conducting structure disposed on the substrate. The first conducting structure is electrically connected to the sensing region or device region. The chip package further includes a passive element vertically stacked on the substrate. The passive element and the first conducting structure are positioned side by side.

Embodiments of the invention provide a method for forming a chip package. The method includes providing a substrate. The substrate includes a sensing region or device region. The method also includes forming a first conducting structure on the substrate. The first conducting structure is electrically connected to the sensing region or device region. The method further includes vertically stacking a passive element on the substrate. The passive element and the first conducting structure are positioned side by side.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1E are cross-sectional views of some exemplary embodiments of a method for forming a chip package according to the invention.

FIG. 2 is a cross-sectional view of some exemplary embodiments of a passive element according to the invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. The disclosed contents of the present disclosure include all the embodiments derived from claims of the present disclosure by those skilled in the art. In addition, the present disclosure may repeat reference numbers and/or letters in the various embodiments. This repetition is for the purpose of simplicity and clarity, and does not imply any relationship between the different embodiments and/or configurations discussed. Furthermore, when a first layer is referred to as being on or overlying a second layer, the first layer may be in direct contact with the second layer, or spaced apart from the second layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, microfluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint-recognition devices, microactuators, surface acoustic wave devices, pressure sensors, ink printer heads, and so on.

The aforementioned wafer-level packaging process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level packaging process. In addition, the aforementioned wafer-level packaging process may also be adapted to form a chip package having multilayer integrated circuit devices by stacking a plurality of wafers having integrated circuits or to form a system-in-package (SIP).

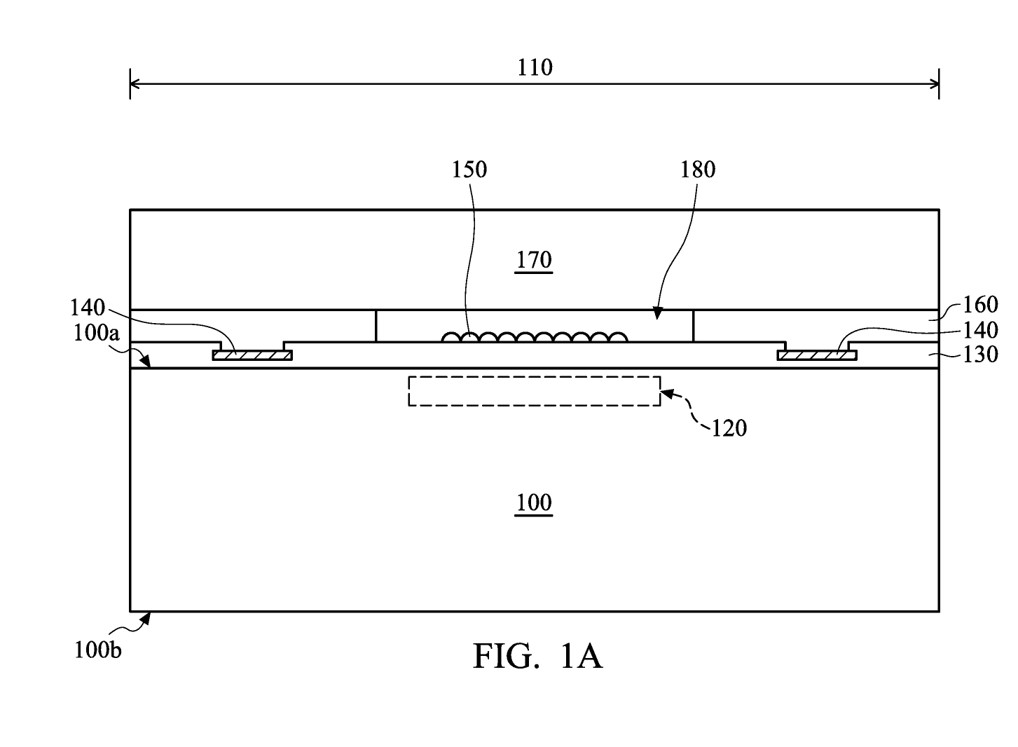

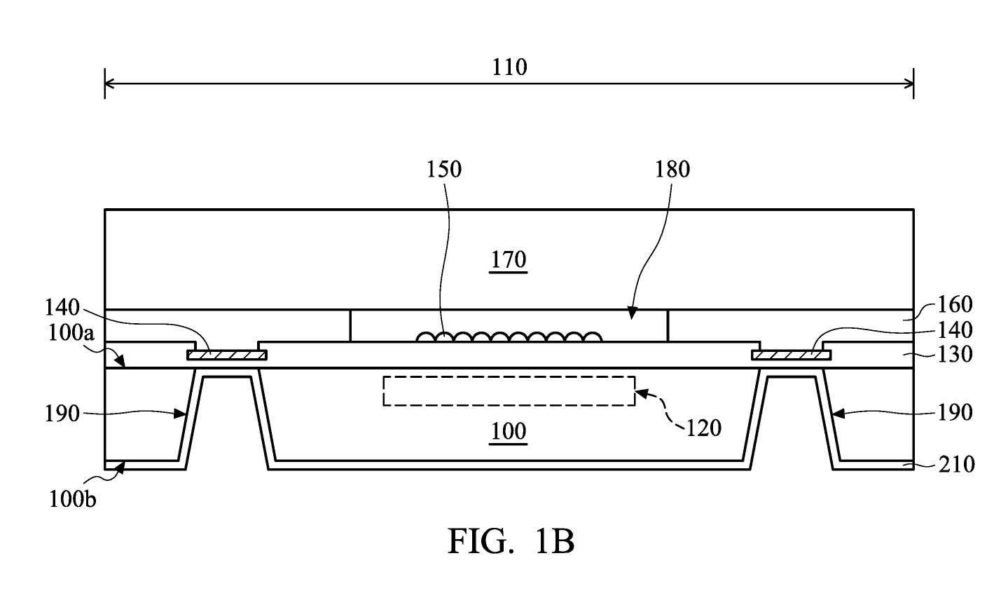

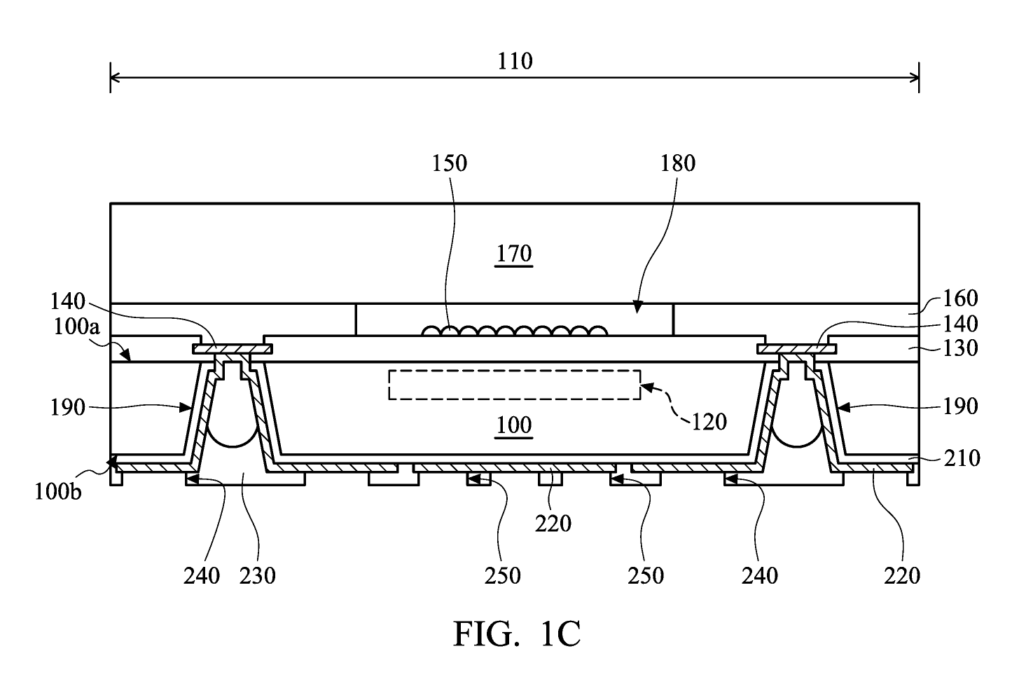

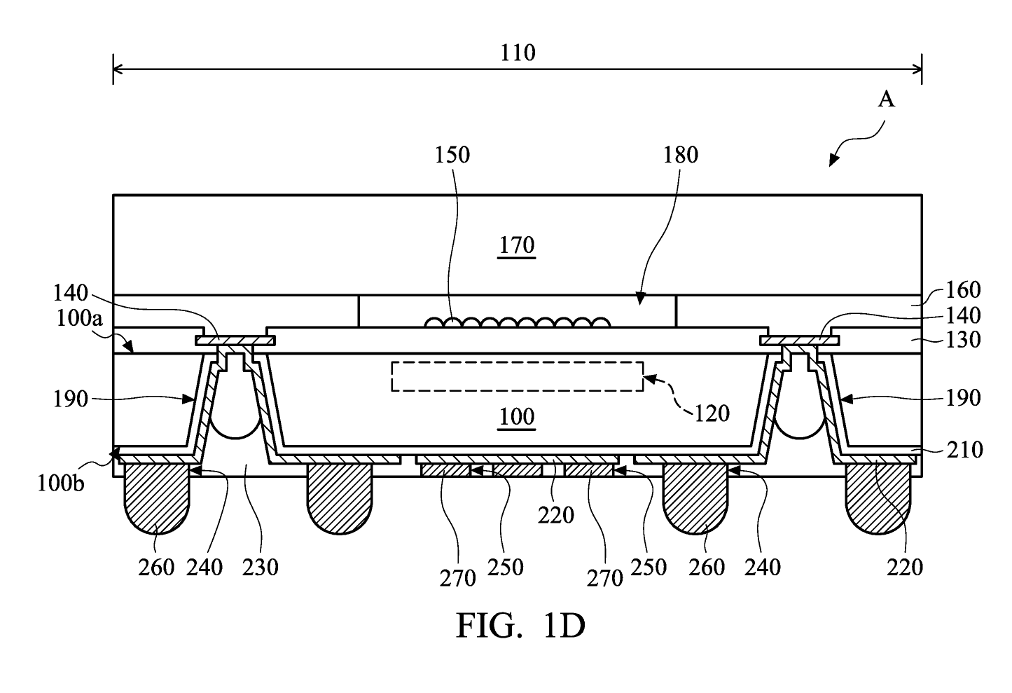

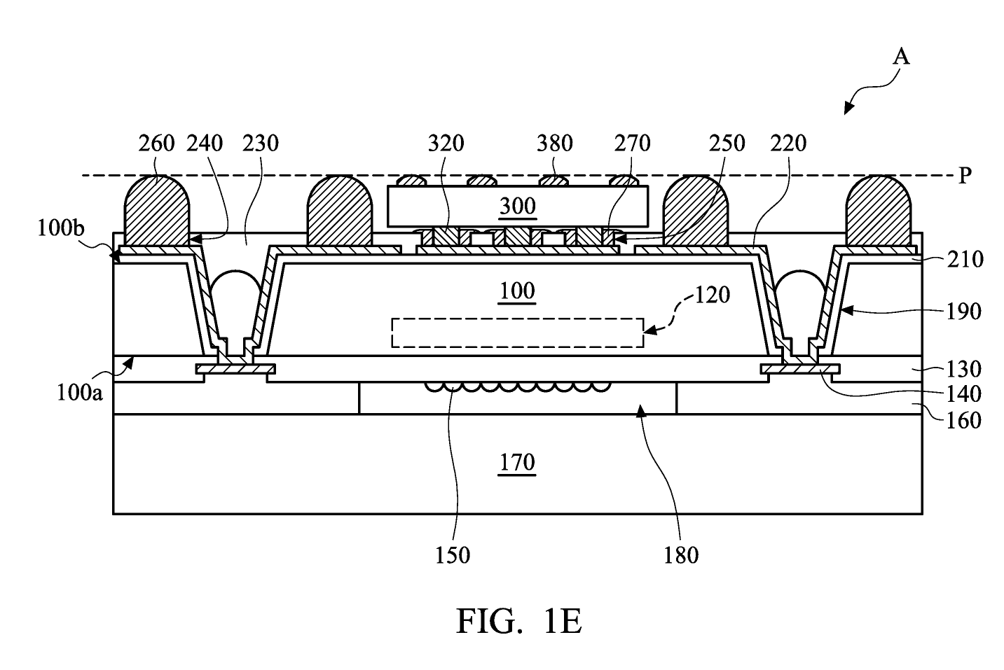

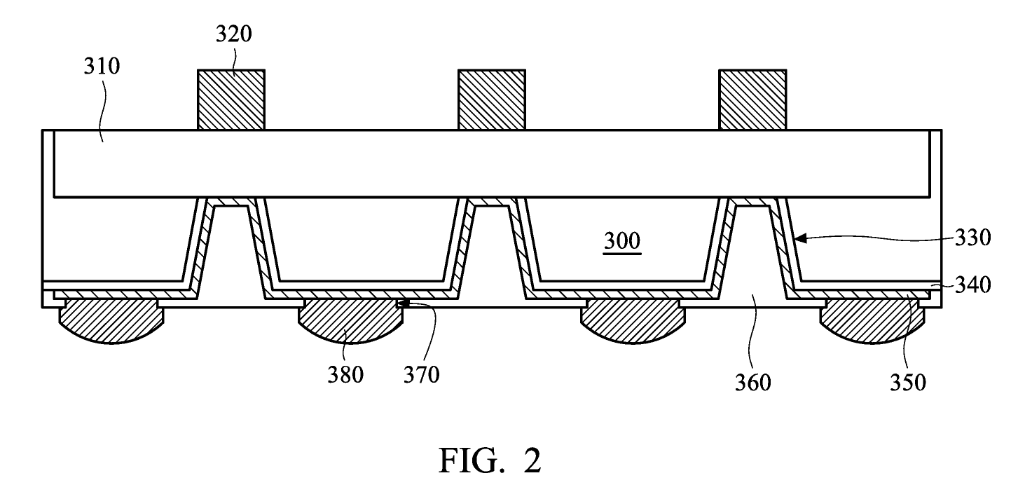

Referring to FIGS. 1E and 2, FIG. 1E is a cross-sectional view of some exemplary embodiments of a chip package according to the invention, and FIG. 2 is a cross-sectional view of some exemplary embodiments of a passive element according to the invention. The chip package comprises a chip package structure A having a substrate 100. The substrate 100 has a first surface 100a and a second surface 100b opposite thereto. In some embodiments, the substrate 100 is a silicon substrate or another semiconductor substrate.

In some embodiments, there is a sensing region or device region 120 in the substrate 100. The sensing region or device region 120 may be adjacent to the first surface 100a. The sensing region or device region 120 comprises a sensing element and/or an active element (such as a transistor). In some embodiments, the sensing region or device region 120 comprises light-sensing elements or other suitable optoelectronic elements. In some other embodiments, the sensing region or device region 120 may comprise a biometric sensing element (such as a fingerprint-recognition element) or a sensing element which is configured to sense environmental characteristics (such as a temperature-sensing element, a humidity-sensing element, a pressure-sensing element or a capacitance-sensing element) or another suitable sensing element.

There is an insulating layer 130 on the first surface 100a of the substrate 100. In general, the insulating layer 130 may be made of an interlayer dielectric (ILD) layer, inter-metal dielectric (IMD) layers and a covering passivation layer. To simplify the diagram, only a single insulating layer 130 is depicted herein. In other words, the chip package structure A includes a chip/die which includes the substrate 100 and the insulating layer 130. In some embodiments, the insulating layer 130 may comprise an inorganic material, such as silicon oxide, silicon nitride, silicon oxynitride, metal oxide, a combination thereof, or another suitable insulating material.

In some embodiments, one or more conducting pads 140 are in the insulating layer 130 on the first surface 100a of the substrate 100. In some embodiments, the conducting pads 140 may be a single conducting layer or comprise multiple conducting layers. To simplify the diagram, only two conducting pads 140 comprising a single conducting layer in the insulating layer 130 are depicted herein as an example. In some embodiments, the insulating layer 130 comprises one or more openings exposing the corresponding conducting pads 140. In some embodiments, the sensing region or device region 120 is electrically connected to the conducting pads 140 through interconnection structures (not shown) in the substrate 100.

In some embodiments, an optical element 150 is disposed on the insulating layer 130 and corresponds to the sensing region or device region 120. In some embodiments, the optical element 150 may be a micro-lens array, a color filter layer, another suitable optical element, or a combination thereof. In some other embodiments, the chip package structure A does not comprise the optical element 150.

In some embodiments, a cover plate 170 is disposed on the first surface 100a of the substrate 100 so as to protect the optical element 150. In some other embodiments, the chip package structure A does not comprise the cover plate 170. As a result, the insulating layer 130 and the optical element 150 are exposed. In some embodiments, the cover plate 170 comprises glass, quartz, transparent polymer or another suitable transparent material.

In some embodiments, there is a spacer layer (or dam) 160 between the substrate 100 and the cover plate 170. The spacer layer 160 covers the conducting pads 140 and exposes the optical element 150. In some embodiments, the spacer layer 160, the cover plate 170 and the insulating layer 130 together surround a cavity 180 on the sensing region or device region 120 so that the optical element 150 is located in the cavity 180. In some other embodiments, the chip package structure A does not comprise the spacer layer 160.

In some embodiments, the spacer layer 160 does not substantially absorb moisture. In some embodiments, the spacer layer 160 is non-adhesive, and the cover plate 170 is attached on the substrate 100 through an adhesive layer. In some other embodiments, the spacer layer 160 itself is adhesive. The cover plate 170 can attach to the substrate 100 by the spacer layer 160 so the spacer layer 160 contacts none of the adhesion glue, thereby ensuring that the spacer layer 160 will not move due to the adhesion glue. Furthermore, since the adhesion glue is not needed, the optical element 150 can be prevented from being contaminated by an overflow of adhesion glue.

In some embodiments, the spacer layer 160 may comprise epoxy resin, inorganic materials (such as silicon oxide, silicon nitride, silicon oxynitride, metal oxide or a combination thereof), organic polymer materials (such as polyimide, butylcyclobutene (BCB), parylene, polynaphthalenes, fluorocarbons or acrylates), a photoresist material or another suitable insulating material.

In some embodiments, multiple openings 190 penetrate the substrate 100 and extend into the insulating layer 130, thereby exposing the corresponding conducting pad 140 from the second surface 100b of the substrate 100. In some embodiments, the diameter of the openings 190 adjacent to the first surface 100a is less than that of the openings 190 adjacent to the second surface 100b. As a result, the openings 190 have inclined sidewalls. In some other embodiments, the diameter of the openings 190 adjacent to the first surface 100a is equal to or greater than that of the openings 190 adjacent to the second surface 100b.

In some embodiments, an insulating layer 210 is disposed on the second surface 100b of the substrate 100, conformally extends to the sidewalls of the openings 190, and exposes the conducting pads 140. In some embodiments, the insulating layer 210 may comprise epoxy resin, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates) or another suitable insulating material.

In some embodiments, a patterned redistribution layer 220 is disposed on the second surface 100b of the substrate 100, and conformally extends to the sidewalls and the bottoms of the openings 190. The redistribution layer 220 is electrically isolated from the substrate 100 by the insulating layer 210. The redistribution layer 220 is in direct electrical contact with, or is indirectly electrically connected to, the exposed conducting pads 140 through the openings 190. As a result, the redistribution layer 220 in the openings 190 is also referred to as a through silicon via (TSV). In some other embodiments, the redistribution layer 220 is electrically connected to the corresponding conducting pads 140 by way of T-contact.

In some embodiments, the redistribution layer 220 may comprise aluminum, copper, gold, platinum, nickel, tin, a combination thereof, a conductive polymer material, a conductive ceramic material (such as indium tin oxide or indium zinc oxide), or another suitable conductive material.

In some embodiments, a protection layer 230 is disposed on the second surface 100b of the substrate 100, and fills the openings 190 to cover the redistribution layer 220. In some embodiments, the protection layer 230 does not fill up the openings 190, so that a hole is formed between the redistribution layer 220 and the protection layer 230 within the openings 190. In some other embodiments, the protection layer 230 fills up the openings 190. In some embodiments, the protection layer 230 has a substantially even surface. In some other embodiments, the protection layer 230 has an uneven surface. For example, the surface of the protection layer 230 has a recessed part corresponding to the openings 190.

In some embodiments, the protection layer 230 may comprise epoxy resin, solder mask, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates), or another suitable insulating material.

In some embodiments, the protection layer 230 on the second surface 100b of the substrate 100 has openings exposing portions of the redistribution layer 220. In some embodiments, the openings 240 have a width greater than that of the openings 250. In some other embodiments, the width of the openings 240 is equal to or less than that of the openings 250.

In some embodiments, multiple first conducting structures 260 (such as solder balls, bumps or conductive pillars) are disposed in the openings 240 of the protection layer 230 to electrically connect to the exposed redistribution layer 220 and the sensing region or device region 120. In some embodiments, the conducting structures 260 comprise tin, lead, copper, gold, nickel, another suitable conductive material, or a combination thereof.

In some embodiments, a bonding layer 270 is disposed in the openings 250 of the protection layer 230 and is electrically connected to the exposed redistribution layer 220. In some embodiments, the bonding layer 270 may comprise tin, lead, copper, gold, nickel, another suitable bonding material, or a combination thereof. In some embodiments, the material of the bonding layer 270 is the same as that of the first conducting structures 260. In some other embodiments, the material of the bonding layer 270 is different from that of the first conducting structures 260.

In some embodiments, a passive element 300 is vertically stacked over the substrate 100. The passive element 300 and the substrate 100 are not laterally arranged. The passive element 300 and the first conducting structures 260 are positioned at the same side of the substrate 100. The passive element 300 and the first conducting structures 260 are laterally arranged. Furthermore, the passive element 300 and the optical element 150 are positioned at two opposite sides of the substrate 100. The passive element 300 and the cover plate 170 are positioned at two opposite sides of the substrate 100. In some embodiments, the first conducting structures 260 discontinuously or discretely surround the passive element 300.

In some embodiments, the thickness of the passive element 300 is less than that of the substrate 100. In some embodiments, the size of the passive element 300 is less than that of the substrate 100. Moreover, when the size of the substrate 100 is large enough or the size of the passive element 300 is small enough, more than one passive element 300, having the same or different functions, can be disposed on the second surface 100b of the substrate 100. In some embodiments, the passive element 300 corresponds to the center of the substrate 100. In some embodiments, the passive element 300 completely or partially overlaps the sensing region or device region 120. In some other embodiments, the passive element 300 does not overlap the sensing region or device region 120.

In some embodiments, the passive element 300 may be an integrated passive device (IPD). In some other embodiments, the passive element 300 may be a resistor, a capacitor, an inductor, another suitable passive element, or a combination thereof. As shown in FIG. 2, the passive element 300 comprises a device region 310. The circuits in the device region 310 may form a resistor, a capacitor, an inductor, another suitable passive element, or a combination thereof.

In some embodiments, multiple bonding structures 320 are disposed on the top surface of the passive element 300, as shown in FIG. 2. The bonding structures 320 are electrically connected to the device region 310. In some embodiments, the bonding structures 320 and the substrate 100 are positioned at the same side of the passive element 300.

In some embodiments, the bonding structures 320 are disposed in the openings 250 and protrude from the openings 250. In some embodiments, the bonding structures 320 are in direct contact with the redistribution layer 220 and are partially surrounded by the bonding layer 270, as shown in FIG. 1E. In some other embodiments, the bonding structures 320 are embedded in the bonding layer 270. A portion of the bonding layer 270 may be vertically sandwiched between the bonding structures 320 and the redistribution layer 220. In some embodiments, the bonding structures 320, the first conducting structures 260 and/or the bonding layer 270 are disposed on the redistribution layer 220. Accordingly, the bonding structures 320, the first conducting structures 260 and/or the bonding layer 270 are positioned at substantially the same level.

In some embodiments, the thickness of the bonding structures 320 is in a range from about 10 μm to about 20 μm, such as 15 μm. In some embodiments, the bonding structures 320 comprise copper, aluminum, another suitable conductive material, or a combination thereof. The bonding structures 320 comprising copper can provide good electrical connection paths between the substrate 100 and the passive element 300, and reduce the attenuation of the power and/or signal. Furthermore, the bonding structures 320 also provide the chip package structure A with good heat transfer paths.

In some embodiments, the material of the bonding structures 320 is different from that of the first conducting structures 260 and/or the bonding layer 270. In some other embodiments, the material of the bonding structures 320 is the same as that of the first conducting structures 260 and/or the bonding layer 270. In some embodiments, each of the bonding structures 320 is a conductive pillar, a conductive layer, or another suitable bonding structure.

As shown in FIG. 2, multiple openings 330 extend in the passive element 300. The device region 310 is partially exposed from the bottom surface of the passive element 300 by the openings 330. In some embodiments, the structure of the openings 330 is the same or similar to that of the openings 190. Moreover, an insulating layer 340 is disposed on the bottom surface of the passive element 300. The insulating layer 340 conformally extends to the sidewalls of the openings 330 and partially exposes the device region 310. In some embodiments, the structure and/or the material of the insulating layer 340 is the same or similar to that of the insulating layer 210.

In some embodiments, a patterned redistribution layer 350 is disposed on the bottom surface of the passive element 300, and conformally extends to the sidewalls and the bottoms of the openings 330. The redistribution layer 350 is electrically connected to the exposed device region 310 through the openings 330. As a result, the redistribution layer 350 in the openings 330 is also referred to as a TSV. In some embodiments, the structure and/or the material of the redistribution layer 350 is the same or similar to that of the redistribution layer 220. Moreover, a protection layer 360 is disposed on the bottom surface of the passive element 300, and fills the openings 330 to cover the redistribution layer 350. In some embodiments, the structure and/or the material of the protection layer 360 is the same or similar to that of the protection layer 230.

In some embodiments, the protection layer 360 on the bottom surface of the passive element 300 has openings 370 exposing portions of the redistribution layer 350. In some embodiments, multiple second conducting structures 380 (such as solder balls, bumps or conductive pillars) are disposed in the openings 370 of the protection layer 360 to electrically connect to the exposed redistribution layer 350. The second conducting structures 380 and the substrate 100 are positioned at two opposite sides of the passive element 300.

In some embodiments, the size of the second conducting structures 380 is less than that of the first conducting structures 260. In some embodiments, the thickness of the second conducting structures 380 is less than that of the bonding structures 320. In some other embodiments, the thickness of the second conducting structures 380 is equal to or greater than that of the bonding structures 320.

In some embodiments, the second conducting structures 380 comprise tin, lead, copper, gold, nickel, another suitable conductive material, or a combination thereof. In some embodiments, the material of the second conducting structures 380 is the same as that of the first conducting structures 260 and/or the bonding structures 320. In some other embodiments, the material of the second conducting structures 380 is different from that of the first conducting structures 260 and/or the bonding structures 320.

As shown in FIG. 1E, the top (or the top surface) of the second conducting structures 380 and the (or the top surface) of the first conducting structures 360 are substantially aligned with the plane P. In other words, the top (or the top surface) of the second conducting structures 380 and the top (or the top surface) of the first conducting structures 360 are substantially coplanar. In some embodiments, the total thickness of the bonding structures 320, the passive element 300 and the second conducting structures 380 is substantially the same as the thickness of the first conducting structures 360.

In some embodiments, the substrate 100 and the passive element 300 can be bonded on a circuit board (not shown). In some embodiments, the substrate 100 is physically connected to the circuit board through the first conducting structures 260. The sensing region or device region 120 in the substrate 100 is electrically connected to the circuit board through the first conducting structures 260. In some embodiments, the passive element 300 is physically and electrically connected to the circuit board through the second conducting structures 380.

In some embodiments, because of the circuit design, the chip package transmits the power through the second conducting structures 380 and transmits the signals through the first conducting structures 260. In some other embodiments, the chip package transmits the power through the second conducting structures 380 and some of the first conducting structures 260, and transmits the signals through other first conducting structures 260. The power influences the electromagnetic effect more than the signals. Accordingly, the power is transmitted through the second conducting structures 380. The passive element 300 is used to provide a stable current. As a result, the reduction of the power is prevented as much as possible.

According to the aforementioned embodiments of the invention, one or more passive elements can be integrated in a chip package without increasing the size of the chip package. A circuit board, which the chip package will be connected to, does not need to have a space for disposing the passive element. As a result, the size of the circuit board can be reduced. Accordingly, the size of an electronic product made using the chip package can be reduced further. Furthermore, since the passive element is directly connected to the chip, the electrical transmission paths between the passive element and the chip are significantly shortened. Therefore, the power and/or signal attenuation can be prevented. Noise can be effectively avoided. The quality and reliability of the electronic product are enhanced.

In some embodiments mentioned above, the chip package comprises a front side illumination (FSI) sensor device. However, in some other embodiments, the chip package may comprise back side illumination (BSI) sensor devices. In addition, although some embodiments mentioned above described an optical sensing device as examples, embodiments of the invention are not limited thereto. Embodiments of the invention can be applied to incorporate a passive element into any suitable chip package.

Some exemplary embodiments of a method for forming a chip package according to the invention are illustrated in FIGS. 1A to 1E and 2. FIGS. 1A to 1E are cross-sectional views of some exemplary embodiments of a method for forming a chip package according to the invention. FIG. 2 is a cross-sectional view of some exemplary embodiments of a passive element according to the invention.

Referring to FIG. 1A, a substrate 100 is provided. The substrate 100 has a first surface 100a and a second surface 100b opposite thereto. The substrate 100 comprises multiple chip regions 110. To simplify the diagram, only a single chip region 110 is depicted herein. In some embodiments, the substrate 100 is a silicon substrate or another semiconductor substrate. In some embodiments, the substrate 100 is a silicon wafer so as to facilitate the wafer-level packaging process.

In some embodiments, there is a sensing region or device region 120 in the substrate 100 in each of the chip regions 110. The sensing region or device region 120 may be adjacent to the first surface 100a. The sensing region or device region 120 comprises a sensing element. In some embodiments, the sensing region or device region 120 comprises light-sensing elements or other suitable optoelectronic elements. In some other embodiments, sensing region or device region 120 may comprise a biometric sensing element (such as a fingerprint-recognition element) or a sensing element which is configured to sense environmental characteristics (such as a temperature-sensing element, a humidity-sensing element, a pressure-sensing element or a capacitance-sensing element) or another suitable sensing element.

There is an insulating layer 130 on the first surface 100a of the substrate 100. In general, the insulating layer 130 may be made of an ILD layer, IMD layers and a covering passivation layer. To simplify the diagram, only a single insulating layer 130 is depicted herein. In some embodiments, the insulating layer 130 may comprise an inorganic material, such as silicon oxide, silicon nitride, silicon oxynitride, metal oxide or a combination thereof or another suitable insulating material.

In some embodiments, one or more conducting pads 140 are in the insulating layer 130 in each of the chip regions 110. In some embodiments, the conducting pads 140 may be a single conducting layer or comprise multiple conducting layers. To simplify the diagram, only two conducting pads 140 comprising a single conducting layer in the insulating layer 130 are depicted herein as an example. In some embodiments, the insulating layer 130 in each of the chip regions 110 comprises one or more openings exposing the corresponding conducting pads 140. In some embodiments, elements in the sensing region or device region 120 may be electrically connected to the conducting pads 140 through interconnection structures (not shown) in the substrate 100.

In some embodiments, the aforementioned structure may be fabricated by sequentially performing a front-end process and a back-end process of a semiconductor device. For example, the sensing region or device region 120 may be formed in the substrate 100 during the front-end process. The insulating layer 130, the interconnection structures, and the conducting pads 140 may be formed on the substrate 100 during the back-end process. In other words, the following method for forming a chip package proceeds to subsequent packaging processes on the aforementioned structure after the back-end process is completed.

In some embodiments, each of the chip regions 110 comprises an optical element 150 disposed on the first surface 100a of the substrate 100 and corresponding to the sensing region or device region 120. In some embodiments, the optical element 150 may be a micro-lens array, a color filter layer, another suitable optical element, or a combination thereof.

Afterward, a spacer layer 160 is formed on a cover plate 170. The cover plate 170 is bonded onto the first surface 100a of the substrate 100 by the spacer layer 160. The spacer layer 160 forms a cavity 180 between the substrate 100 and the cover plate 170 in each of the chip regions 110, so that the optical element 150 is located in the cavity 180 and the optical element 150 in the cavity 180 is protected by the cover plate 170. In some other embodiments, the spacer layer 160 is formed on the substrate 100, and then the cover plate 170 is bonded to the substrate 100.

In some embodiments, the cover plate 170 comprises glass, quartz, transparent polymer or another suitable transparent material. In some embodiments, the spacer layer 160 is formed by a deposition process (such as a coating process, a physical vapor deposition process, a chemical vapor deposition process or another suitable process). Furthermore, the spacer layer 160 may comprise epoxy resin, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates) or another suitable insulating material. Alternatively, the spacer layer 160 may comprise a photoresist material, and may be patterned by exposure and developing processes to expose the optical element 150.

Referring to FIG. 1B, a thinning process (such as an etching process, a milling process, a grinding process or a polishing process) using the cover plate 170 as a carrier substrate is performed on the second surface 100b of the substrate 100 to reduce the thickness of the substrate 100.

Afterwards, multiple openings 190 are formed in the substrate 100 in each of the chip regions 110 by a lithography process and an etching process (such as a dry etching process, a wet etching process, a plasma etching process, a reactive ion etching process, or another suitable process). The openings 190 expose the insulating layer 130 from the second surface 100b of the substrate 100.

In some embodiments, the first openings 190 correspond to the conducting pads 140 and penetrate the substrate 100. The diameter of the first openings 190 adjacent to the first surface 100a is less than that of the openings 190 adjacent to the second surface 100b. Therefore, the openings 190 have inclined sidewalls so that the difficulty of the process for subsequently forming layers in the openings 190 is reduced, and reliability is improved. For example, since the diameter of the openings 190 adjacent to the first surface 100a is less than that of the openings 190 adjacent to the second surface 100b, layers (such as an insulating layer and a redistribution layer) subsequently formed in the openings 190 can be easily deposited on a corner between the openings 190 and the insulating layer 130 to avoid affecting electrical connection paths or inducing leakage current problems.

In some embodiments, an additional opening (or trench) is formed in the substrate 100 between the adjacent chip regions 110 by a lithography process and an etching process. The additional opening extends along the scribed line between the adjacent chip regions 110 and penetrates the substrate 100, such that portions of the substrate 100 in the chip regions 110 are separated from each other. Moreover, the additional opening may have inclined sidewalls. That is, the portions of the substrate 100 in the chip regions 110 have inclined edge sidewalls.

Referring to FIG. 1C, an insulating layer 210 is formed on the second surface 100b of the substrate 100 by a deposition process (such as a coating process, a physical vapor deposition process, a chemical vapor deposition process or another suitable process). In some embodiments, the insulating layer 210 conformally extends to the sidewalls and the bottoms of the openings 190. In some embodiments, the insulating layer 210 may comprise epoxy resin, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates) or another suitable insulating material.

Next, the insulating layer 210 on the bottom of the openings 190 and the underlying insulating layer 130 are removed by lithography and etching processes. As a result, the openings 190 extend into the insulating layer 130 and expose the corresponding conducting pads 140.

Afterwards, a patterned redistribution layer 220 is formed on the insulating layer 210 by a deposition process (such as a coating process, a physical vapor deposition process, a chemical vapor deposition process, an electroplating process, an electroless plating process or another suitable process) and lithography and etching processes. In some embodiments, the redistribution layer 220 conformally extends to the sidewalls and the bottoms of the openings 190. The redistribution layer 220 is electrically isolated from the substrate 100 by the insulating layer 210. The redistribution layer 220 is in direct electrical contact with or indirectly electrically connected to the exposed conducting pads 140 through the openings 190. In some embodiments, the redistribution layer 220 may comprise aluminum, copper, gold, platinum, nickel, tin, a combination thereof, a conductive polymer material, a conductive ceramic material (such as indium tin oxide or indium zinc oxide), or another suitable conductive material.

Referring to FIG. 1D, a protection layer 230 may be formed on the second surface 100b of the substrate 100 by a deposition process. The protection layer 230 fills the openings 190 to cover the redistribution layer 220. In some embodiments, the protection layer 230 may comprise epoxy resin, solder mask, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates), or another suitable insulating material.

In some embodiments, the protection layer 230 partially fills the openings 190, so that a hole is formed between the redistribution layer 220 and the protection layer 230 within the openings 190. In some embodiments, the interface between the protection layer 230 and the hole has an arcuate contour.

Since the protection layer 230 partially fills the openings 190 and leaves the hole, the hole can be a buffer between the redistribution layer 220 and the protection layer 230 in thermal cycles induced in subsequent processes. Undesirable stress, which is induced between the redistribution layer 220 and the protection layer 230 as a result of mismatched thermal expansion coefficients, is reduced. The redistribution layer 220 is prevented from being excessively pulled by the protection layer 230 when external temperature or pressure dramatically changes. As a result, problems such as peeling or disconnection of the redistribution layer 220, which is close to the conducting pad structure, are avoidable.

Next, openings 240 and 250 may be formed in the protection layer 230 on the second surface 100b of the substrate 100 by lithography and etching processes so as to expose portions of the redistribution layer 220. In some embodiments, the width of the openings 240 is greater than that of the openings 250. In some other embodiments, the width of the openings 240 may be equal to or less than that of the openings 250.

Referring to FIG. 1D, a bonding layer 270 is filled in the openings 250 of the protection layer 230 by a screen printing process or another suitable process. The bonding layer 270 is electrically connected to the exposed redistribution layer 220. In some embodiments, the bonding layer 270 partially fills the openings 250. In some other embodiments, the bonding layer 270 fills up the openings 250. In some embodiments, the bonding layer 270 in the openings 250 protrudes from the openings 250. In some other embodiments, the bonding layer 270 in the openings 250 further extends on the protection layer 230. In some embodiments, the bonding layer 270 may comprise tin, lead, copper, gold, nickel, another suitable bonding material, or a combination thereof.

Subsequently, first conducting structures 260 are filled in the openings 240 of the protection layer 230 by a screen printing process or another suitable process. The first conducting structures 260 are electrically connected to the exposed redistribution layer 220 and the sensing region or device region 120. The first conducting structures 260 fill up the openings 240 and protrude from the openings 240. In some embodiments, the first conducting structures 260 may comprise tin, lead, copper, gold, nickel, another suitable conductive material, or a combination thereof. In some embodiments, the formation method of the first conducting structures 260 is the same as that of the bonding layer 270.

Afterwards, the protection layer 230, the substrate 100, the insulating layer 130, the spacer layer 160 and the cover plate 170 are diced along the scribed line (not shown) between the adjacent chip regions 110. As a result, multiple independent chip package structures A are formed. For example, a dicing saw or laser may be used to perform the dicing process. A laser cutting process can be performed in order to avoid displacement of upper and lower layers.

Referring to FIG. 1E, a passive element 300 is placed on one of the chip package structures A. Afterward, a reflow process is performed so that the passive element 300 and one of the chip package structures A are bonded and electrically connected to each other. Specifically, the passive element 300 is bonded on the second surface 100b of the substrate 100. As a result, the passive element 300 and the substrate 100 are vertically stacked. In the embodiment, the size of the passive element 300 is less than that of the substrate 100. Moreover, when the size of the substrate 100 is large enough or the size of the passive element 300 is small enough, more than one passive element 300, having the same or different functions, can be disposed on the second surface 100b of the substrate 100.

In some embodiments, the first conducting structures 260 and the passive element 300 are positioned at the same side of the substrate 100. The passive element 300 and the first conducting structures 260 are laterally arranged. Furthermore, the passive element 300 and the optical element 150 are positioned at two opposite sides of the substrate 100. The passive element 300 and the cover plate 170 are positioned at two opposite sides of the substrate 100. In some embodiments, the passive element 300 is surrounded by multiple first conducting structures 260. In some embodiments, the passive element 300 is an IPD. In some other embodiments, the passive element 300 is a resistor, a capacitor, an inductor or another suitable passive element.

Referring to FIG. 2, the passive element 300 comprises a device region 310. The circuits in the device region 310 may form a resistor, a capacitor, an inductor, another suitable passive element, or a combination thereof. In some embodiments, before the passive element 300 is bonded to the chip package structures A, multiple bonding structures 320 are formed on the top surface of the passive element 300 and electrically connected to the device region 310. In some embodiments, the bonding structures 320 comprise copper, aluminum, another suitable conductive material, or a combination thereof.

As shown in FIG. 2, multiple openings 330 are formed in the passive element 300, and partially expose the device region 310 from the bottom surface of the passive element 300. An insulating layer 340 is formed on the bottom surface of the passive element 300, conformally extends to the sidewalls of the openings 330, and partially exposes the device region 310. A patterned redistribution layer 350 is formed on the bottom surface of the passive element 300, and conformally extends to the sidewalls and the bottoms of the openings 330. A protection layer 360 is formed on the bottom surface of the passive element 300, and fills the openings 330 to cover the redistribution layer 350. Moreover, openings 370 are formed in the protection layer 360 on the bottom surface of the passive element 300 to expose portions of the redistribution layer 350.

In some embodiments, the arrangement and formation method of the openings 330, the insulating layer 340, the redistribution layer 350, the protection layer 360 and the openings 370 is the same or similar to that of the openings 190, the insulating layer 210, the redistribution layer 220, the protection layer 230 and the openings 240, respectively. They are not described again for brevity.

In some embodiments, a thinning process (such as an etching process, a milling process, a grinding process or a polishing process) is performed on the bottom surface of the passive element 300 to reduce the thickness of the passive element 300.

Subsequently, multiple second conducting structures 380 are filled in the openings 370 of the protection layer 360 by a screen printing process or another suitable process to electrically connect to the exposed redistribution layer 350. The second conducting structures 380 fills up the openings 370 and protrude from the openings 370. In some embodiments, the second conducting structures 380 may comprise tin, lead, copper, gold, nickel, another suitable conductive material, or a combination thereof. In some embodiments, the formation method of the second conducting structures 380 is the same as that of the first conducting structures 260 and/or the bonding layer 270.

In some embodiments, the substrate of the passive element 300 is a wafer, and a wafer-level packaging and a dicing process are performed to form multiple passive element 300s. It should be realized that the passive element 300 shown in FIG. 2 is an example. The structure of the passive element 300 is not limited thereto. Moreover, to simplify the diagram, the openings 330, the insulating layer 340, the redistribution layer 350, the protection layer 360 and the openings 370 shown in FIG. 2 are not depicted in FIG. 1E.

As mentioned above, after the passive element 300 is placed on the chip package structure A, the first conducting structures 260, the bonding layer 270, and the second conducting structures 380 are simultaneously reflowed. As a result, the passive element 300 is bonded to and electrically connected to the chip package structure A through the bonding structures 320 and the bonding layer 270.

In some embodiments, the bonding structures 320 are embedded in the bonding layer 270 so that the bonding structures 320 are surrounded by the bonding layer 270. As a result, a strong and solid connecting bond is formed between the passive element 300 and the substrate 100. In some embodiments, a portion of the bonding layer 270 is extruded by the bonding structure 320 and extends from the opening 250 over the protective layer 230. In some other embodiments, the bonding layer 270 may not extend over the protective layer 230.

In some embodiments, the bonding structures 320, the first conducting structures 260 and/or the bonding layer 270 are disposed on the redistribution layer 220. Accordingly, the bonding structures 320, the first conducting structures 260 and/or the bonding layer 270 are positioned at substantially the same level. In some other embodiments, a portion of the bonding layer 270 is sandwiched between the bonding structures 320 and the redistribution layer 220. Accordingly, the bonding structures 320 are positioned at a different level than the first conducting structure 260 and/or the bonding layer 270.

As shown in FIG. 1E, the bonding structures 320 are embedded within the bonding layer 270 so that the top of the second conducting structures 380 and the top of the first conducting structures 260 are substantially aligned with the plane P. In other words, the top of the second conducting structures 380 is substantially coplanar with the top of the first conducting structures 260. In some embodiments, the thickness of the passive element 300 is less than the thickness of the first conducting structures 260. In some embodiments, the total thickness of the bonding structures 320, the passive element 300, and the second conducting structures 380 is substantially the same as the thickness of the first conducting structures 260.

In some embodiments, the passive element 300 and the chip package structure A are bonded to a circuit board (not shown) by performing a reflow process. The substrate 100 is physically and electrically connected to the circuit board through the first conducting structures 260. The passive element 300 is physically and electrically connected to the circuit board through the second conducting structures 380. Since the top of the second conductive structures 380 is substantially coplanar with the top of the first conductive structures 260, the passive element 300 and the chip package structure A can be smoothly and directly bonded to the circuit board. As a result, one or more passive elements can be integrated directly into the chip package. The connected circuit board no longer needs to have a space for disposing the passive element. Accordingly, the size of the electronic product can be reduced further.

Furthermore, since the passive element 300 is directly connected to the chip package structure A, the electrical transmission paths between the passive element 300 and the chip package structure A are drastically shortened. As a result, the power can be transmitted completely without deterioration of the signal. Noise can be effectively avoided. Therefore, the quality and reliability of the electronic product are enhanced.

It should be realized that although the embodiments of FIGS. 1A to 1E provide a method for forming a chip package with an FSI sensing device, the method for forming external electrical connection paths of the chip (such as the opening in the substrate, the redistribution layer, the protection layer, or the conducting structures therein) and the passive element can be implemented to the processes of a BSI sensing device or another type chip package.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a substrate comprising a sensing region or device region;
a first conducting structure on the substrate, wherein the first conducting structure is electrically connected to the sensing region or device region; and
a passive element vertically stacked on the substrate, wherein the passive element and the first conducting structure are positioned side by side.

2. The chip package as claimed in claim 1, further comprising a second conducting structure, wherein the second conducting structure and the substrate are disposed on two opposite sides of the passive element.

3. The chip package as claimed in claim 2, wherein a material of the second conducting structure is the same as that of the first conducting structure.

4. The chip package as claimed in claim 2, wherein a top of the second conducting structure is substantially aligned with that of the first conducting structure.

5. The chip package as claimed in claim 2, wherein a size of the second conducting structure is less than that of the first conducting structure.

6. The chip package as claimed in claim 1, wherein the passive element is bonded on the substrate through a bonding structure.

7. The chip package as claimed in claim 6, wherein the bonding structure and the first conducting structure is positioned at a substantial same level.

8. The chip package as claimed in claim 6, wherein the bonding structure is surrounded by a bonding layer, and a material of the bonding layer is different from that of the bonding structure.

9. The chip package as claimed in claim 8, wherein the material of the bonding layer is the same as that of the first conducting structure.

10. The chip package as claimed in claim 1, wherein a thickness of the passive element is less than that of the first conducting structure.

11. The chip package as claimed in claim 1, wherein the passive element overlaps the sensing region or device region.

12. A method for forming a chip package, comprising:
providing a substrate, wherein the substrate comprises a sensing region or device region;
forming a first conducting structure on the substrate, wherein the first conducting structure is electrically connected to the sensing region or device region; and
vertically stacking a passive element on the substrate, wherein the passive element and the first conducting structure are positioned side by side.

13. The method for forming a chip package as claimed in claim 12, further comprising forming a bonding layer on the substrate before vertically stacking the passive element on the substrate, wherein the passive element has a bonding structure, and the bonding structure is embedded in the bonding layer after the passive element having the bonding structure is vertically stacked on the substrate.

14. The method for forming a chip package as claimed in claim 13, wherein a formation method of the bonding layer is the same as that of the first conducting structure.

15. The method for forming a chip package as claimed in claim 13, further comprising performing a reflow process on the first conducting structure and the bonding layer.

16. The method for forming a chip package as claimed in claim 12, further comprising:
forming a second conducting structure on the passive element before vertically stacking the passive element on the substrate, wherein the passive element with the second conducting structure is vertically stacked on the substrate.

17. The method for forming a chip package as claimed in claim 16, wherein a top of the second conducting structure is substantially aligned with that of the first conducting structure.

18. The method for forming a chip package as claimed in claim 16, wherein a formation method of the second conducting structure is the same as that of the first conducting structure.

19. The method for forming a chip package as claimed in claim 16, further comprising performing a reflow process on the first conducting structure and the second conducting structure.

20. The method for forming a chip package as claimed in claim 12, further comprising performing a dicing process on the substrate before vertically stacking the
